(19) United States
(12) Patent Application Publication
(10) Pub. No.: US 2011/0068402 A1
(43) Pub. Date: Mar. 24, 2011

(54) THIN FILM TRANSISTOR AND METHOD FOR PRODUCING THIN FILM TRANSISTOR

(75) Inventors: Satoru Takasawa, Sammu-shi (JP); Satoru Ishibashi, Sammu-shi (JP); Kyuzo Nakamura, Chigasaki-shi (JP); Tadashi Masuda, Tomisato-shi (JP)

(73) Assignee: ULVAC, INC.,, Chigasaki-shi (JP)

(21) Appl. No.: 12/881,641

(22) Filed: Sep. 14, 2010

Related U.S. Application Data
(63) Continuation of application No. PCT/JP2009/057176, filed on Apr. 8, 2009.

(30) Foreign Application Priority Data
Apr. 15, 2008 (JP) 2008-106119

(51) Int. Cl. H01L 29/786; H01L 21/336

(52) U.S. Cl. 257/347; 438/158; 257/E21.411; 257/E29.273

(57) ABSTRACT

A metallic wiring film, which is not exfoliated even when exposed to a plasma of hydrogen, is provided. A metallic wiring film 20a is constituted by an adhesion layer 51 in which an additive metal is added to copper and a low-resistance metallic layer 52, which is made of pure copper, is disposed on the adhesion layer 51. When the additive metal made of at least one of Ti, Zr and Cr, and oxygen are included in a copper alloy which is in the adhesion layer 51 and a source electrode and a drain electrode are formed from it, copper does not precipitate at an interface between the adhesion layer 51 and the silicon layer even when being exposed to the hydrogen plasma, which prevents exfoliation from occurring between the adhesion layer 51 and the silicon layer. If the amount of additive metal increases, the adhesion layer 51 cannot be etched with an etching liquid for etching the low-resistance metallic layer 52, so that the maximum additional amount to permit the etching to be performed is the upper limit.

This application is a continuation of International Application No. PCT/JP2009/057176 filed on Apr. 8, 2009, which claims priority to Japanese Patent Document No. 2008-106119, filed on Apr. 15, 2008. The entire disclosure of the prior applications are herein incorporated by references in their entireties.

### BACKGROUND OF THE INVENTION

The present invention relates to a transistor having electrode films composed of a copper alloy and a method for producing such a transistor.

### BACKGROUND ART

Conventionally, metallic wiring films are connected to a source area and a drain area of a TFT (thin film transistor) inside an electronic circuit of, such as, the TFT or the like.

Recently, since the TFTs and the wiring films have been made finer and finer, wiring films which have copper as a main ingredient, are used to obtain wiring films having low resistances.

However, experiments revealed that although the wiring films made mainly of copper have high adhesion to silicon, exfoliation may occur when TFTs are produced by using the copper wiring films, which is the problem to avoid.

See, Japan Patent documents JP-A 2001-73131 and JP-A 11-54458.

### SUMMARY OF THE INVENTION

The inventors of the present invention have determined the cause for deterioration of the adhesion between the copper wiring film and the silicon layer lies in a treatment of improving the characteristics of the TFT in which the silicon layer is exposed to a hydrogen plasma during a production step of the TFT so as to restore the damage of the silicon layer.

Since pure copper has poor adhesion to silicon, a metallic wiring film to form a source electrode film and a drain electrode film is designed in a two-layer structure of an adhesion layer made of a copper alloy to which magnesium and oxygen are added in order to render high adhesion to silicon, and a low-resistance metallic layer made of pure copper having a resistance lower than that of the adhesion layer.

It is considered that when such a metallic wiring film is exposed to the hydrogen plasma, a copper compound in the adhesion layer is reduced, so that pure Cu precipitates at an interface between the silicon and the adhesion layer, which causes the deterioration of the adhesion.

As a result of investigation and study of additives for preventing pure copper from precipitation at the interface between the copper wiring film and silicon, the inventors of the present invention have thus discovered the use of oxides of Ti, Zr and Cr in the production of the present invention.

In other words, an embodiment of the present invention is directed to a method for producing a thin film transistor of an inverted staggered type, comprising the steps of: forming a gate electrode on an object to be processed; forming a gate insulation layer on the gate electrode; forming a semiconductor layer on the gate insulation layer; forming an ohmic contact layer on the semiconductor layer; forming a metallic wiring layer on the ohmic contact layer; and forming a first and a second ohmic contact layers, a source electrode, and a drain electrode by patterning the ohmic contact layer and the metallic wiring film. The step of forming the metallic wiring film includes a step of sputtering a target of a copper alloy having an additive metal including at least one of Ti, Zr or Cr and copper in a vacuum atmosphere with a gas including a sputtering gas and oxidizing gas for forming an adhesion layer having copper, the additive metal and oxygen on the ohmic contact layer.

The present embodiment may be directed to a method for producing the thin film transistor, wherein the additive metal is included in the copper alloy target at a rate of between at least 5 atom % and at most 30 atom %.

The present embodiment is further directed to a method for producing the thin film transistor, which includes the step of, after forming the adhesion layer, forming a metallic low-resistance layer on the adhesion layer, the metallic low-resistance layer having a higher copper content rate than that of the adhesion layer and a resistance lower than that of the adhesion layer.

The present embodiment is further directed to a method for producing the thin film transistor, wherein a CO₂ gas is used as the oxidizing gas, and the CO₂ gas is included in a range of between at least 3 parts by volume and at most 30 parts by volume relative to 100 parts by volume of the sputtering gas.

The present embodiment is further directed to a method for producing the thin film transistor, wherein an O₂ gas is used as the oxidizing gas, and the O₂ gas is included in a range of between at least 3 parts by volume and at most 15 parts by volume relative to 100 parts by volume of the sputtering gas.

An embodiment of the present invention is directed to a thin film transistor of an inverted staggered type, including: a gate electrode formed on an object to be processed; a gate insulation layer formed on the gate electrode; a semiconductor layer formed on the gate insulation layer; a first and a second ohmic contact layers, which are separated from each other, formed on the semiconductor layer; and a source electrode and a drain electrode formed on the first and the second ohmic contact layers, respectively. The source electrode and the drain electrode have adhesion layers on surfaces, which contact the first and the second ohmic contact layers, the adhesion layers having a copper alloy including an additive metal made of at least one of Ti, Zr or Cr, and oxygen.

The present embodiment is further directed to a thin film transistor, wherein the first and second ohmic contact layers are n-type semiconductor layers.

The present embodiment is further directed to a thin film transistor, wherein a low-resistance metallic layer, which has a content rate of copper higher than that of the adhesion layer and a resistance lower than that of the adhesion layer, is arranged on the adhesion layer.

The present embodiment is further directed to a thin film transistor, wherein the additive metal is included at a rate of between at least 5 atom % and at most 30 atom % relative to atoms of the metals including the additive metal in the adhesion layer.

In the present invention, a semiconductor which has silicon (such as, polysilicon, amorphous silicon or the like) as a main ingredient is called silicon layer.

Since the electrode film does not exfoliate even when exposed to the hydrogen plasma, the yield increases.

### BRIEF DESCRIPTION OF THE DRAWINGS

FIG. 1(a) is a cross-sectional view for illustrating a method for producing the transistor used in an embodiment of the present invention.

FIG. 1(b) is a cross-sectional view for illustrating the method for producing the transistor used in an embodiment of the present invention.

FIG. 1(c) is a cross-sectional view for illustrating the method for producing the transistor used in an embodiment of the present invention.

FIG. 1(d) is a cross-sectional view for illustrating the method for producing the transistor used in an embodiment of the present invention.

FIG. 1(e) is a cross-sectional view for illustrating the method for producing the transistor used in an embodiment of the present invention.

FIG. 1(f) is a cross-sectional view for illustrating the method for producing the transistor used in an embodiment of the present invention.

FIG. 1(g) is a cross-sectional view for illustrating the method for producing the transistor used in an embodiment of the present invention.

FIG. 1(h) is a cross-sectional view for illustrating the method for producing the transistor used in an embodiment of the present invention.

FIG. 2 is a cross-sectional view for illustrating a metallic wiring film.

FIG. 3 is a schematic block diagram for illustrating a film forming apparatus to be used for producing the transistor in an embodiment of the present invention.

FIG. 4 is a graph for showing a comparison between the specific resistances of an adhesion layer using a CO₂ gas and an adhesion layer using an O₂ gas.

### DETAILED DESCRIPTION OF THE INVENTION

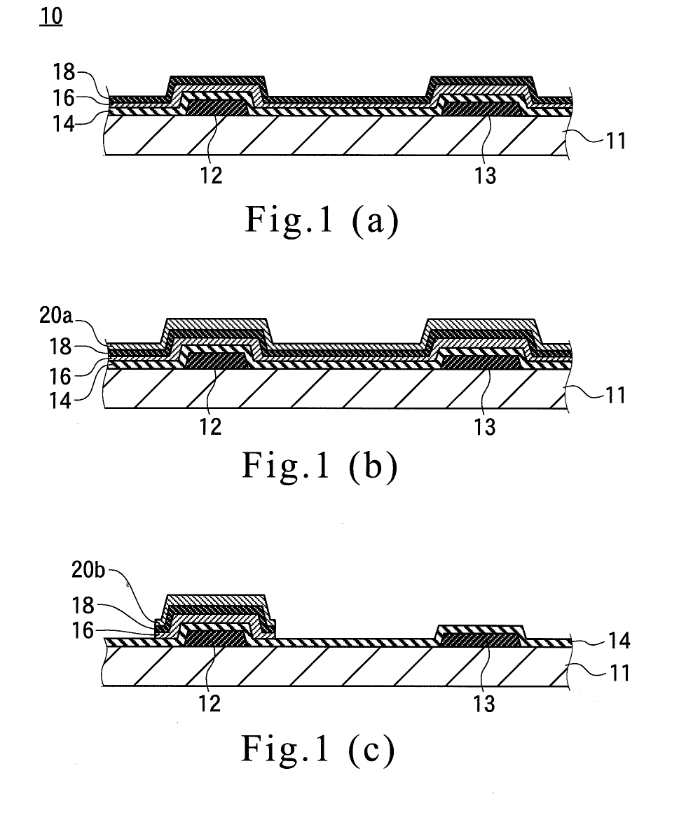

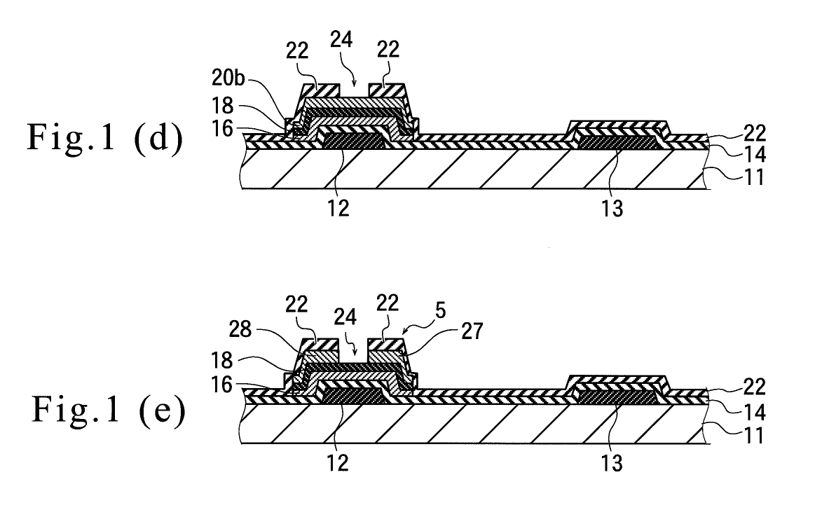

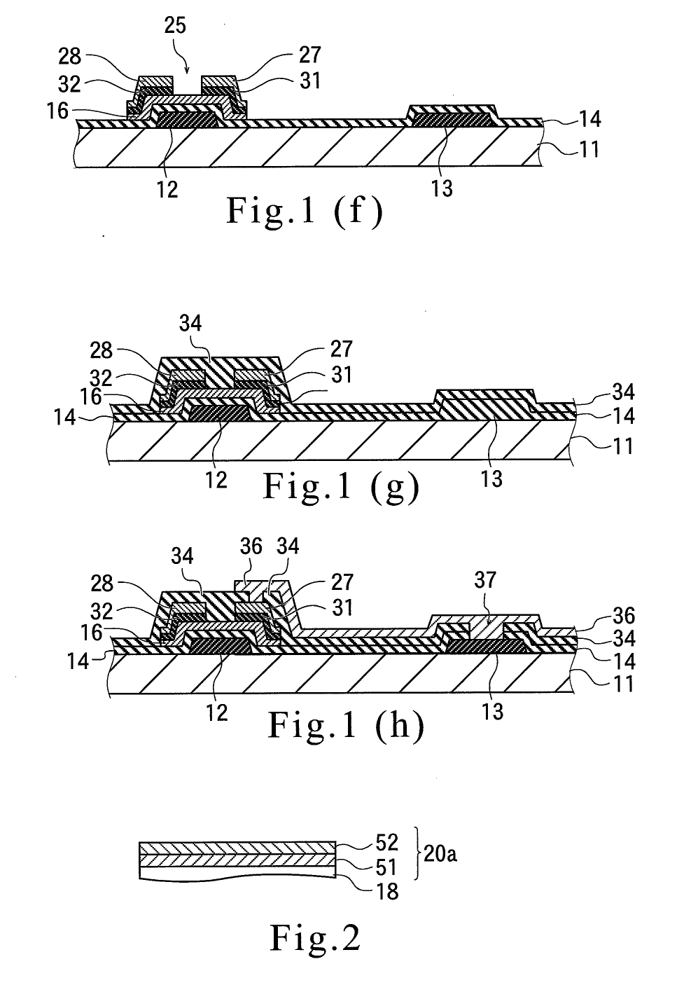

In FIG. 1(a), a reference numeral 10 denotes an object to be processed, for which the transistor producing method according to an embodiment of the present invention is to be used.

The object 10 to be processed has a transparent substrate 11 made of glass or the like; and a gate electrode 12 and a pixel electrode 13 are arranged spaced-apart on the transparent substrate 11.

A gate insulation film 14, a silicon layer 16 and an n-type silicon layer 18 are placed on the transparent substrate 11 in this order from a side of the transparent substrate 11, covering the gate electrode 12 and the pixel electrode 13. The n-type silicon layer 18 is a silicon layer in which a resistance value is made smaller than that of the silicon layer 16 by adding an impure substance. In this embodiment, the n-type silicon layer 18 and the silicon layer 16 are constituted by amorphous silicon, but they may be a single crystal or polycrystal. The gate insulation layer 14 is an insulation film (such as, a thin film of silicon nitride or the like), but may be a film of silicon oxynitride film or another insulation film.

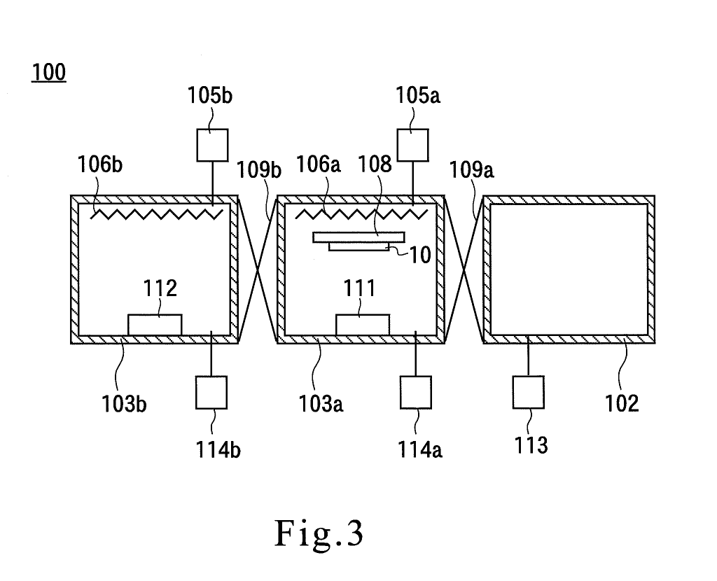

In FIG. 3, a reference numeral 100 denotes a film forming apparatus for forming a metallic wiring film on a surface of the object 10 to be processed.

The film forming apparatus 100 has a carrying in/out chamber 102, a first film forming chamber 103a, and a second film forming chamber 103b. The carrying in/out chamber 102 and the first film forming chamber 103a, and the first film forming chamber 103a and the second film forming chamber 103b are connected via gate valves 109a and 109b, respectively.

Vacuum evacuating systems 113, 114a, 114b are connected to the carrying in/out chamber 102 and the first and second film forming chambers 103a, 103b, respectively. Consequently, while the gate valves 109a, 109b are closed, the interiors of the first and second film forming chambers 103a, 103b are preliminarily evacuated to vacuum.

Next, a door between the carrying in/out chamber 102 and the air is opened, an object 10 to be processed is carried into the carrying in/out chamber 102, and the door is closed; then, after the interior of the carrying in/out chamber 102 is evacuated to vacuum, the gate valve 109a is opened, and the object 10 to be processed is moved into the first film forming chamber 103a to be held on a substrate holder 108.

A copper alloy target 111 and a pure copper target 112 are placed on sides of bottom walls inside the first and second film forming chambers 103a, 103b, respectively; and the object 10 to be processed is held on the substrate holder 108 such that the n-type silicon layer 18 may face each of the targets 111, 112.

Gas introduction systems 105a, 105b are connected to the first and second film forming chambers 103a, 103b, respectively; and accordingly, when the copper alloy target 111 is sputtered while introducing a sputtering gas and an oxidizing gas from the gas introduction system 105a in a state such that the interior of the first film forming chamber 103a is being evacuated to vacuum, sputtered particles made of a constitutent material of the copper alloy target 111 reach a surface of the n-type silicon layer 18, and an adhesion layer which contacts the n-type silicon layer 18 is formed.

The copper alloy target 111 includes copper and at least one of the additive metals of Ti (titanium), Zr (zirconium) and Cr (chromium); and when the number of atoms of the copper and the additive metal is taken as 100 atom %, the additive metal is contained at a rate of between at least 5 atom % and at most 30 atom %.

The oxidizing gas is a gas which oxidizes the additive metal and produces an oxide of the additive metal. Consequently, when the copper alloy target 111 is sputtered, an adhesion layer having copper as a main ingredient and the oxide of the additive metal is formed on a surface of the object 10 to be processed.

Thereafter, when the substrate holder 108 on which the object 10 to be processed is held is moved to the second film forming chamber 103b, and the sputtering gas is introduced from the gas introduction system 105b to sputter the pure copper target 112, sputtered particles made of copper atoms as the constituent material of the pure copper target 112 reach the surface of the object 10 to be processed; and a low-resistance metallic layer made of pure copper is formed on the surface of the adhesion layer. The oxidizing gas is not introduced into the second film forming chamber 103b.

In FIG. 1(b), a reference numeral 20a denotes a metallic wiring film composed of the adhesion layer and the low-resistance layer; and reference numerals 51, 52 in FIG. 2 denote the adhesion layer and the low-resistance metallic layer, respectively.

A resist layer is placed on a surface of the portion of the metallic wiring film 20a, which is located above the gate electrode 12; and by etching a laminated film composed of the metallic wiring film 20a, the n-type silicon layer 18 and the silicon layer 16, the portion of the laminated film which is not covered with the resist film is removed.

FIG. 1(c) shows a state in which the resist film is removed after etching the laminated film, and a reference numeral 20b shows the metallic wiring film that remains with the resist film thereon.

Next, as shown in FIG. 1 (d), a patterned resist film 22 is placed on the metallic wiring film 20b, and then, by immersion into an etching liquid of a mixed liquid of phosphoric acid, nitric acid, and acetic acid; a mixed liquid of sulfuric acid, nitric acid, and acetic acid; or a solution of ferric chloride or the like, in such a state that a surface of the metallic wiring film 20b is exposed at a bottom face of an opening 24 of the resist film 22, the exposed portion of the metallic wiring film 20b is etched. Thus, the metallic wiring film 20b is patterned.

By this patterning, the opening 24, where the n-type silicon layer 18 is exposed on the bottom face, is formed in the portion of the metallic wiring film 20b which is above the gate electrode 12, so that the metallic wiring film 20b is divided by the opening 24 in order to form a source electrode film 27 and a drain electrode film 28 as shown in FIG. 1 (e). Thus, the transistor 5 used in an embodiment of the present invention is attained.

Next, the object is carried into an etching device, then by etching the n-type silicon layer 18, which is exposed to the bottom face of the opening 24 by being exposed to a plasma of an etching gas, a silicon layer 16 is exposed at a bottom face of an opening 24 formed in the n-type silicon layer 18.

The opening 24 formed in the n-type silicon layer 18 is in a position above the gate electrode 12; and the n-type silicon layer 18 is divided into a source area 31 and a drain area 32 by the opening 24.

A surface of the silicon layer 16 is exposed to a surface of the opening 24; and when the silicon layer 16 is exposed to the plasma of the etching gas when etching the n-type silicon layer 18, hydrogen atoms are lost from the surface of the silicon layer 16, which may result in the formation of dangling bonds.

Such dangling bonds cause inferiority in characteristics of the TFT (such as, leak current). In order to modify the dangling bonds with hydrogen again, hydrogen is introduced to generate a hydrogen plasma; and then the silicon layer 16, which is exposed at the bottom of an opening 25 is exposed to the plasma of the hydrogen gas in such a state that the source electrode film 27 and the drain electrode film 28 are exposed as shown in FIG. 1 (f), silicon atoms on the surface of the silicon layer 16 bind to hydrogen, thereby reducing the dangling bonds.

In the metallic wiring film 20a (20b) in this embodiment of the present invention, the source electrode film 27 and the drain electrode film 28 includes the adhesion layer 51 having copper as a main ingredient and the additive metal at the rate of between at least 5 atom % and at most 30 atom %; and the adhesion layer 51 adheres tightly to silicon and to silicon dioxide of the transistor, so that even when the source electrode film 27 and the drain electrode film 28 are exposed to the hydrogen plasma, copper does not precipitate at the interface between the n-type silicon layer 18 (and the source area 31 and the drain area 32), which prevents the electrode film constituted by the metallic wiring film 20a (20b) (such as, the source electrode film 27, the drain electrode film 28 or the like) from exfoliation.

Following the treatment with the hydrogen plasma, after a passivation film 34 is formed as shown in FIG. 1 (g), and contact holes 37 are formed in the passivation film 34, a liquid crystal display panel is obtained by forming a transparent electrode film 36 in order to connect the source electrode film 27 or the drain electrode film 28 with the pixel electrode 13 as shown in FIG. 1 (h).

Gases which are able to be used for etching the silicon layer (including a polysilicon layer and an amorphous silicon layer) are Cl₂, HBr, Cl₂, HCl, CBrF₃, SiCl₄, BCl₃, CHF₃, PCl₃, HI, I₂ or the like. One kind of these halogen gases may be used alone as the etching gas, or a mixture of two or more kinds thereof may be used as the etching gas. Further, an additive gas, (such as, O₂, N₂, SF₆, N₂, Ar, NH₃ or the like), other than one of the halogen gases can be added to the etching gas.

The halogen gases listed above are able to be used to etch other objects to be etched, (such as, silicon nitride (SiN), silicon oxide (SiO₂), GaAs, SnO₂, Cr, Ti, TiN, W, Al or the like).

For etching gases for the polysilicon (for example, Cl₂, Cl₂+HBr, Cl₂+O₂, CF₄+O₂, SF₆, Cl₂+N₂, Cl₂+HCl, HBr+Cl₂+SF₆ or the like) can be used.

For etching gases for Si (for example, SF₆, C₄F₈, CBrF₃, CF₄+O₂, Cl₂, SiCl₄+Cl₂, SF₆+N₂+Ar, BCl₂+Cl₂+Ar, CF₄, NF₃, SiF₄, BF₃, XeF₂, ClF₃, SiCl₄, PCl₃, BCl₃, HCl, HBr, Br₂, HI, I₂ or the like) can be used.

For etching gases for the amorphous silicon (for example, CF₄+O₂, Cl₂+SF₆ or the like) can be used.

When an adhesion layer 51 is formed with 100% of an additive metal (a metallic Ti film, a metallic Zr film or the like) and a metallic wiring film is obtained by laminating a low-resistance metallic layer 52 of pure copper on a surface thereof, the low-resistance metallic layer 52 made of pure copper and the low-resistance metallic layer 52 having copper as a main ingredient can be etched by using the mixed liquid of phosphoric acid, nitric acid, acetic acid; the mixed liquid of sulfuric acid, nitric acid, acetic acid; or the solution of ferric chloride as the etchant. However, because the adhesion layer 51 made of 100% of the additive metal or the adhesion layer 51 including a large amount of the additive metal largely differs from the low-resistance metallic layer 52 made of pure copper in etching speeds, the low-resistance metallic layer 52 and the adhesion layer 51 may significantly differ in width. (A pure Ti thin film and a pure Zr thin film are insoluble in the etchant for the low-resistance metallic layer 52 made of pure copper, but can be soluble in a strongly-acid etching liquid of a hydrofluoric acid type; however, since such an etching liquid dissolves glass or Si, it cannot be used for TFTs.)

Consequently, when the adhesion layer 51 of 100% of the additive metal is used as a barrier layer for the silicon layer and a copper thin film is formed thereon, exposing a surface of the barrier film, first of all, by patterning the copper thin film with the use of the etching liquid (such as, the mixed liquid of phosphoric acid, nitric acid, acetic acid or the like), is necessary. Thereafter, a dry etching process is performed by means of an etching gas. This may make the number of necessary steps to increase, and the cost to rise.

In this embodiment of the present invention, since the adhesion layer 51 includes more copper than the additive metal, the adhesion layer 51 and the low-resistance metallic layer 52 can be wet etched by means of the same etching liquid. In addition, since the adhesion layer 51 and the low-resistance metallic layer 52 can be etched with the same resist film without rearranging a resist film, cost becomes low.

### EXAMPLES

A copper alloy target 111 was sputtered with an argon gas used as a sputtering gas and an oxygen gas used as an oxidizing gas, an adhesion layer 51 was formed to 50 nm thick on a glass substrate, and thereafter a low-resistance metallic layer 52 was formed to 300 nm thick on the adhesion layer 51 by sputtering a pure copper target 112 by means of the argon gas, thereby obtaining a metal wiring film of a two-layer structure. The temperature of the substrate was 100° C., the sputtering gas was Ar gas, and the sputtering pressure was 0.4 Pa.

Following exposure of a surface of the formed metallic wiring film to be exposed to a hydrogen plasma, a film of silicon nitride was formed on the surface thereof.

The treatment with a hydrogen gas plasma was such that the flow rate of the hydrogen gas was 500 sccm, the pressure was 200 Pa, the temperature of the substrate was 250° C., the power was 300 W and the time was 60 seconds.

The silicon nitride film was formed such that respective gases were introduced into a CVD apparatus, in which the substrate was arranged, at the rates of SiH₄: 20 sccm, NH₃ gas: 300 sccm and N₂ gas: 500 sccm, the pressure was 120 Pa, the temperature of the substrate was 250° C., and the power was 300 W.

Adhesion as deposited (i.e., adhesion of a film, which when immediately after formation still remains to be treated in ways that include annealing) of the metallic wiring film before the exposure to the hydrogen plasma and adhesion (adhesion after the H₂ plasma treatment) after the formation of a film of silicon nitride on a surface thereof, following the exposure to the hydrogen plasma, were measured by a tape test in which an adhesive tape was adhered and was then peeled. Evaluations were carried out by taking examples having surfaces of the glass substrates marked with crosses “X”, and different ones marked with circles “◯”.

Experiments were carried out, while content rates of additive metals and the introduction rate of an oxidizing gas were changed. Evaluation results are shown as “adhesion” in the following Tables 1 to 3.

Also, after the same metallic wiring film as explained above was formed on a surface of a silicon wafer, it was annealed in a vacuum atmosphere; and following removal of the metallic wiring film by etching, the surface is observed in order to determine if there is a diffusion of copper into the silicon with an SEM.

In each of the experiments, the sputtering gas was argon gas, the oxidizing gas was oxygen gas, and the partial pressure of the sputtering gas in the sputtering atmosphere was 0.4 Pa.

Further, a target including an additive metal was sputtered by means of CO₂ gas as oxidizing gas in place of oxygen gas. With Ar gas used as a sputtering gas and Ti used as an additive metal, the adhesion and barrier properties were evaluated. The partial pressure of the sputtering gas was the same as explained above.

Observation results were shown as “barrier property” in the following Tables 1 to 3 (with oxygen gas used as an oxidizing gas) and Table 4 (with CO₂ used as an oxidizing gas). Examples in which diffusion was observed were marked with crosses “X”, while those in which diffusion was not observed were marked with circles “◯”.

TABLE 1

| | Ti Addition | O₂ Addition | | Barrior | |
|---|---|---|---|---|---|
| | Amount | Amount | | Property | Adhesion After |
| Copper alloy | (at %) | (%) | Adhesion | 300° C. | H₂ Plasma Treatment |
| Cu/Cu—Ti—O | 3 | — | X | X | X |
| | | 1 | X | X | X |
| | | 3 | ◯ | ◯ | X |
| | | 5 | ◯ | ◯ | X |
| | | 7 | ◯ | ◯ | X |
| | | 10 | ◯ | ◯ | X |
| | | 15 | ◯ | ◯ | X |
| | 5 | — | ◯ | X | ◯ |
| | | 1 | ◯ | ◯ | ◯ |
| | | 3 | ◯ | ◯ | ◯ |
| | | 5 | ◯ | ◯ | X |
| | | 7 | ◯ | ◯ | X |
| | | 10 | ◯ | ◯ | X |
| | | 15 | ◯ | ◯ | X |
| | 10 | — | ◯ | X | ◯ |
| | | 1 | ◯ | ◯ | ◯ |
| | | 3 | ◯ | ◯ | ◯ |
| | | 5 | ◯ | ◯ | ◯ |
| | | 7 | ◯ | ◯ | X |
| | | 10 | ◯ | ◯ | X |
| | | 15 | ◯ | ◯ | X |
| | 30 | — | ◯ | X | ◯ |
| | | 1 | ◯ | ◯ | ◯ |
| | | 3 | ◯ | ◯ | ◯ |
| | | 5 | ◯ | ◯ | ◯ |
| | | 7 | ◯ | ◯ | ◯ |
| | | 10 | ◯ | ◯ | ◯ |
| | | 15 | ◯ | ◯ | ◯ |

O₂ addition amount is the O₂ introduction amount where introduction amount of sputtering gas is 100.
Ti addition amount is the number of the Ti atoms where the number of the atoms of the entire metals is inclusive of Ti.

TABLE 2

| | Zr Addition | O₂ Addition | | Barrior | |
|---|---|---|---|---|---|
| | Amount | Amount | | Property | Adhesion After |
| Copper alloy | (at %) | (%) | Adhesion | 300° C. | H₂ Plasma Treatment |
| Cu/Cu—Zr—O | 3 | — | X | X | X |
| | | 1 | X | X | X |
| | | 3 | ◯ | ◯ | X |
| | | 5 | ◯ | ◯ | X |
| | | 7 | ◯ | ◯ | X |
| | | 10 | ◯ | ◯ | X |
| | | 15 | ◯ | ◯ | X |
| | 5 | — | ◯ | X | ◯ |
| | | 1 | ◯ | ◯ | ◯ |
| | | 3 | ◯ | ◯ | ◯ |
| | | 5 | ◯ | ◯ | X |
| | | 7 | ◯ | ◯ | X |
| | | 10 | ◯ | ◯ | X |
| | | 15 | ◯ | ◯ | X |
| | 10 | — | ◯ | X | ◯ |
| | | 1 | ◯ | ◯ | ◯ |
| | | 3 | ◯ | ◯ | ◯ |
| | | 5 | ◯ | ◯ | ◯ |
| | | 7 | ◯ | ◯ | X |
| | | 10 | ◯ | ◯ | X |
| | | 15 | ◯ | ◯ | X |
| | 30 | — | ◯ | X | ◯ |
| | | 1 | ◯ | ◯ | ◯ |
| | | 3 | ◯ | ◯ | ◯ |
| | | 5 | ◯ | ◯ | ◯ |
| | | 7 | ◯ | ◯ | ◯ |
| | | 10 | ◯ | ◯ | ◯ |
| | | 15 | ◯ | ◯ | ◯ |

O₂ addition amount is the O₂ introduction amount where introduction amount of sputtering gas is 100.
Zr addition amount is the number of the Zr atoms where the number of the atoms of the entire metals is inclusive of Zr.

TABLE 3

| | Cr Addition | O₂ Addition | | Barrior | |
|---|---|---|---|---|---|
| | Amount | Amount | | Property | Adhesion After |
| Copper alloy | (at %) | (%) | Adhesion | 300° C. | H₂ Plasma Treatment |
| Cu/Cu—Cr—O | 3 | — | X | X | X |
| | | 1 | X | X | X |
| | | 3 | ◯ | ◯ | X |
| | | 5 | ◯ | ◯ | X |
| | | 7 | ◯ | ◯ | X |
| | | 10 | ◯ | ◯ | X |
| | | 15 | ◯ | ◯ | X |
| | 5 | — | ◯ | X | ◯ |
| | | 1 | ◯ | ◯ | ◯ |
| | | 3 | ◯ | ◯ | ◯ |
| | | 5 | ◯ | ◯ | X |
| | | 7 | ◯ | ◯ | X |
| | | 10 | ◯ | ◯ | X |
| | | 15 | ◯ | ◯ | X |
| | 10 | — | ◯ | X | ◯ |
| | | 1 | ◯ | ◯ | ◯ |
| | | 3 | ◯ | ◯ | ◯ |
| | | 5 | ◯ | ◯ | ◯ |
| | | 7 | ◯ | ◯ | ◯ |
| | | 10 | ◯ | ◯ | X |
| | | 15 | ◯ | ◯ | X |
| | 30 | — | ◯ | X | ◯ |
| | | 1 | ◯ | ◯ | ◯ |
| | | 3 | ◯ | ◯ | ◯ |
| | | 5 | ◯ | ◯ | ◯ |
| | | 7 | ◯ | ◯ | ◯ |
| | | 10 | ◯ | ◯ | ◯ |
| | | 15 | ◯ | ◯ | ◯ |

O₂ addition amount is the O₂ introduction amount where introduction amount of sputtering gas is 100.
Cr addition amount is the number of the Cr atoms where the number of the atoms of the entire metals is inclusive of Cr.

TABLE 4

| | | | Barrier | |
|---|---|---|---|---|
| | CO₂ | Adhesion | Property | Adhesion After |
| Metal | (%) | 300° C. | 300° C. | H₂ Plasma Treatment |
| Cu/Cu—Ti—CO₂ | — | ◯ | X | ◯ |
| | 3 | ◯ | ◯ | ◯ |
| | 5 | ◯ | ◯ | ◯ |
| | 7 | ◯ | ◯ | ◯ |
| | 10 | ◯ | ◯ | ◯ |
| | 15 | ◯ | ◯ | ◯ |
| | 20 | ◯ | ◯ | ◯ |
| | 25 | ◯ | ◯ | ◯ |
| | 30 | ◯ | ◯ | X |

The above-listed results indicate that, when the additive metal included at least 5 atom %, adhesion (adhesion before and after the H₂ plasma treatment) and the barrier properties were desirable.

It is also indicated that the oxidizing gas should be introduced in a range of between at least 3 parts by volume and at most 15 parts by volume relative to an introduction amount of 100 parts by volume of the argon gas.

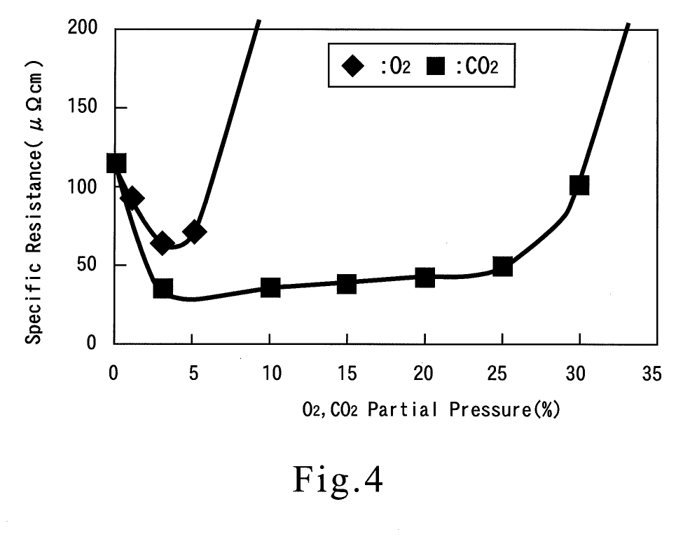

FIG. 4 is a graph showing specific resistances of adhesion layers (corresponding to the adhesion layers in the test results in Table 1) obtained when the copper alloy targets 111 including 10 atom % of Ti as the additive metal were sputtered with Ar gas and O₂ gas and specific resistances of the adhesion layers (corresponding to the adhesion layers in the test results in Table 4) obtained when the sputtering was carried out with Ar gas and CO₂ gas. The specific resistance of CO₂ gas is small in a range wider than that of O₂ gas, which is considered to be due to the oxidizing power of CO₂ gas which is lower than that of O₂ gas.

A minimal value of the specific resistance of oxygen appears in a range of the partial pressure of 3 to 5%. To the contrary, the specific resistance of carbon dioxide is low in a wider range of the partial pressure of 3 to 25%. Consequently, it is easier to adjust the concentration of carbon dioxide. Even if it is difficult to make constant the concentration of the oxidizing gas in a case of a large-scale substrate, a low resistance is obtained by utilizing carbon dioxide such that the partial pressure may be set in the above-discussed wider range; thus, carbon dioxide is more preferable.

Moreover, the minimum value of the specific resistance is lower in the case of carbon dioxide.

A low resistance may not be required when a thin barrier film is formed. However, when a barrier film is formed to be thicker, or when an entire electrode is formed by an alloy layer, with oxidizing gas being introduced, an electrode having a low resistance is required, which makes the use of carbon dioxide more preferable.

Next, the obtained metal wiring film was immersed into an etching liquid, then it is observed whether it is possible to etch both the low-resistance metallic layer 52 and the adhesion layer 51 with the same etching liquid. Phosphoric/nitric/acetic acids (H₃PO₄:HNO₃:CH₃COOH:H₂O)=16:1:2:1 were used in the etching liquid, of which temperature was set at 40° C.

Observation results in the etching are given in the following Table 5. In Table 5, examples in which an etching residue is not observed are shown by a circle “◯”, while those in which an etching residue is observed are shown by a cross “X”.

TABLE 5

| Adhesion Amount | Whether wet etching was possible or not | | |
|---|---|---|---|
| X(at %) | Cu—X at % Ti | Cu—X at % Zr | Cu—X at % Cr |
| 0 | ◯ | ◯ | O |
| 3 | ◯ | ◯ | ◯ |
| 5 | ◯ | ◯ | ◯ |
| 7 | ◯ | ◯ | ◯ |
| 10 | ◯ | ◯ | ◯ |
| 15 | ◯ | ◯ | ◯ |
| 30 | ◯ | ◯ | ◯ |
| 50 | X | X | ◯ |
| 75 | X | X | ◯ |
| 100 | X | X | ◯ |

As to Ti and Zr, it is indicated that at most 30 atom % is desirable. There is no residue of Cr observed, even if it is over 50 atom %; however, since widths of the adhesion layer 51 and the low-resistance metallic layer 52 may significantly differ, at most 30 atom % is preferable in the case of Cr, too.

Moreover, since adhesion of the adhesion layer 51 to silicon or silicon oxide, as well as to the low-resistance metallic layer 52 are desirably higher, the adhesion layer 51 in the present invention includes at least 50% of copper as a component of the low-resistance metallic layer 52.

What is claimed is:

1. A method for producing a thin film transistor of an inverted staggered type, comprising the steps of:
forming a gate electrode on an object to be processed;
forming a gate insulation layer on the gate electrode;
forming a semiconductor layer on the gate insulation layer;
forming an ohmic contact layer on the semiconductor layer;
forming a metallic wiring layer on the ohmic contact layer; and
forming first and second ohmic contact layers, a source electrode, and a drain electrode by patterning the ohmic contact layer and the metallic wiring film,
wherein the step of forming the metallic wiring film includes a step of sputtering a target of a copper alloy having an additive metal including at least one of Ti, Zr or Cr and copper in a vacuum atmosphere with a gas including a sputtering gas and oxidizing gas for forming an adhesion layer having copper, the additive metal and oxygen on the ohmic contact layer.

2. The method for producing the thin film transistor as set forth in claim 1, wherein the copper alloy target is made to include the additive metal at a rate of between at least 5 atom % and at most 30 atom %.

3. The method for producing the thin film transistor as set forth in claim 1, further comprising the step of, after forming the adhesion layer, forming a low-resistance metallic layer on the adhesion layer, the low-resistance metallic layer having a higher copper content rate than that of the adhesion layer and a resistance lower than that of the adhesion layer.

4. The method for producing the thin film transistor as set forth in claim 1, wherein a CO₂ gas is used as the oxidizing gas, and the CO₂ gas is included in a range of between at least 3 parts by volume and at most 30 parts by volume relative to 100 parts by volume of the sputtering gas.

5. The method for producing the thin film transistor as set forth in claim 1, wherein an O₂ gas is used as the oxidizing gas, and the O₂ gas is included in a range of between at least 3 parts by volume and at most 15 parts by volume relative to 100 parts by volume of the sputtering gas.

6. A thin film transistor of an inverted staggered type, comprising:
a gate electrode formed on an object to be processed;
a gate insulation layer formed on the gate electrode;
a semiconductor layer formed on the gate insulation layer;
first and second ohmic contact layers, which are separated from each other, formed on the semiconductor layer; and
a source electrode and a drain electrode formed on the first and the second ohmic contact layers, respectively,
wherein the source electrode and the drain electrode have adhesion layers on surfaces which contact the first and the second ohmic contact layers, the adhesion layers having a copper alloy including an additive metal made of at least one of Ti, Zr or Cr, and oxygen.

7. The thin film transistor as set forth in claim 6, wherein the first and second ohmic contact layers are n-type semiconductor layers.

8. The thin film transistor as set forth in claim 6, wherein a low-resistance metallic layer, which has a content rate of copper higher than that of the adhesion layer and a resistance lower than that of the adhesion layer, is arranged on the adhesion layer.

9. The thin film transistor as set forth in claim 6, wherein the additive metal is included at a rate of between at least 5 atom % and at most 30 atom % relative to atoms of the metals which include the additive metal in the adhesion layer.
